(19) United States
(12) Patent Application Publication
(10) Pub. No.: US 2026/0333592 A1
(43) Pub. Date: Oct. 22, 2026

(54) METHODS AND SYSTEMS FOR THERMALLY CONDUCTIVE CIRCUIT BOARDS

(71) Applicant: Akash Systems, Inc., San Francisco, CA (US)

(72) Inventors: Martha KRUEGER, Allen, TX (US); Larry WITKOWSKI, Plano, TX (US); Paul SAUNIER, Seattle, WA (US); Daniel FRANCIS, Oakland, CA (US); Tyrone D. MITCHELL, JR., Libertyville, IL (US)

(21) Appl. No.: 19/651,449

(22) Filed: Apr. 17, 2026

Related U.S. Application Data
(60) Provisional application No. 63/792,097, filed on Apr. 21, 2025.

(51) Int. Cl. H05K 3/46; H05K 1/02; H05K 3/303; H05K 3/40; H10W 40/00

(52) U.S. Cl. CPC H05K 3/4679; H05K 1/0206; H05K 3/303; H05K 3/4038; H10W 40/037

(57) ABSTRACT

The present disclosure provides methods and systems for thermally conductive circuit boards. The present disclosure provides a method for dissipating heat form electrical circuits, the method comprising supplying a first layer comprising an electrically insulative material with high thermal conductivity, patterning a metal layer on a side of the first layer, attaching a second layer to the first layer comprising through-holes or vias corresponding to at least a portion of the patterned metal layer, and patterning an additional metal layer on a side of the second layer, wherein the layered structure is suitable for use as a heat dissipating circuit board.

### CROSS-REFERENCE

This application claims the benefit of U.S. Provisional Application No. 63/792,097, entitled, “Methods and Systems for Thermally Conductive Circuit Boards,” and filed on Apr. 21, 2025, which is incorporated by reference herein in its entirety.

### BACKGROUND

Modern systems which require fast computation rates use very dense electrical circuits in multi-terminal devices which use great amounts of power to operate. Examples of such multi-terminal devices are a Graphics Processing Unit (GPU) or Central Processing Unit (CPU) of a computer system. Due to inefficiencies inherent in the circuits of these multi-terminal devices, they also generate large amounts of heat during operation. This heat, if not dissipated property, may negatively affect the circuit performance and circuit lifetime. In many cases, it is the removal of the heat from these circuits which is the limiting factor for the multi-terminal devices' optimal performance.

### SUMMARY

Recognized herein is the need for systems and methods for thermally conductive circuit boards.

Provided herein is a method for forming a heat dissipating circuit board, the method comprising (a) supplying a first layer of the heat dissipating circuit board, (b) providing a first metal layer over the first layer, and (c) generating a second layer of the heat dissipating circuit board over the first metal layer, wherein the second layer comprises a plurality of vias in a pattern corresponding to the first metal layer, and wherein the second layer comprises an allotrope of carbon.

In some embodiments, the first layer is a polymer. In some embodiments, (b) comprises patterning the first metal layer. In some embodiments, the plurality of vias in (c) are patterned according to a pattern of the first metal layer. In some embodiments, the first layer is a printed circuit board. In some embodiments, prior to (c) the method further comprises forming the through-holes or vias. In some embodiments, after (c) the method further comprises forming the through-holes or vias. In some embodiments, the plurality of vias in (c) comprise a through via, a blind via, or buried via. In some embodiments, the method further comprises patterning a second metal layer on a side of the second layer of the layered structure opposite the first metal layer. In some embodiments, patterning the first metal layer further comprises a first intermediate layer disposed between the first metal layer and the first layer of heat dissipating circuit board. In some embodiments, the first intermediate layer comprises an electrically conductive material. In some embodiments, the first layer of the heat dissipating circuit board comprises an electrically insulative material with high thermal conductivity (HTc layer). In some embodiments, the first layer has a first side and a second side opposite the first side, and the first metal layer is on the first side of the first layer. In some embodiments, the method further comprises patterning a second metal layer above the second layer of the heat dissipating circuit board. In some embodiments, the method further comprises forming a second intermediate layer disposed between said second metal layer and said second side of the second layer of the heat dissipating circuit board. In some embodiments, the second intermediate layer comprises an electrically conductive material. In some embodiments, the method further comprises providing a second metal layer over the second layer. In some embodiments, the method further comprises generating a third layer of the heat dissipating circuit board over the second metal layer, wherein the third layer comprises a second plurality of vias in a pattern corresponding to the second metal layer, and wherein the second layer comprises an allotrope of carbon. In some embodiments, the second plurality of vias comprises a through via, a blind via, or buried via. In some embodiments, the method further comprises attaching a heat source to the heat dissipating circuit board. In some embodiments, the heat source comprises one or more of a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source. In some embodiments, the heat source comprises a transistor. In some embodiments, the heat source comprises a FET. In some embodiments, the heat source comprises a MOSFET. In some embodiments, the heat source comprises a semiconductor chip. In some embodiments, the heat source comprises a semiconductor die. In some embodiments, the heat source comprises a CPU. In some embodiments, the heat source comprises a microcontroller. In some embodiments, the heat source comprises a GPU. In some embodiments, the heat source comprises a graphics chip. In some embodiments, the heat source comprises a chipset. In some embodiments, the heat source comprises an SoC. In some embodiments, the heat source comprises a capacitor. In some embodiments, the heat source comprises a resistor. In some embodiments, the heat source comprises a regulator. In some embodiments, the heat source comprises a rectifier. In some embodiments, the heat source comprises a diode. In some embodiments, the heat source comprises a transducer. In some embodiments, the heat source comprises an inductor. In some embodiments, the method further comprises attaching a heat dissipative structure to the heat dissipating circuit board. In some embodiments, the heat dissipative structure comprises one or more of a heat sink, a cooling pad, a liquid cooling device, a heat pipe, a vapor chamber, a phase-change cooling device, a thermoelectric cooling device, a Peltier cooling device, a heat spreader, or any suitable heat dissipative structure. In some embodiments, the heat dissipative structure comprises a heat sink. In some embodiments, the heat dissipative structure comprises a cooling pad. In some embodiments, the heat dissipative structure comprises a liquid cooling device. In some embodiments, the heat dissipative structure comprises a heat pipe. In some embodiments, the heat dissipative structure comprises a vapor chamber. In some embodiments, the heat dissipative structure comprises a phase-change cooling device. In some embodiments, the heat dissipative structure comprises a thermoelectric cooling device. In some embodiments, the heat dissipative structure comprises a Peltier cooling device. In some embodiments, the heat dissipative structure comprises a heat spreader. In some embodiments, attaching the heat source to the heat dissipating circuit board comprises forming a metal pad on the heat dissipating circuit board and attaching the heat source to the metal pad. In some embodiments, forming the metal pad on the heat dissipating circuit board comprises thermally connecting the metal pad to the second layer comprising diamond. In some embodiments, attaching the heat dissipative structure to the heat dissipating circuit board comprises forming a metal pad on the heat dissipating circuit board and attaching the heat dissipative structure to the metal pad. In some embodiments, forming the metal pad on the heat dissipating circuit board comprises thermally connecting the metal pad to the second layer comprising diamond. In some embodiments, generating the second layer in (c) comprises depositing the second layer using a deposition method. In some embodiments, the deposition method comprises one or more of chemical vapor deposition (CVD), physical vapor deposition (PVD), sputtering, evaporation deposition, thermal deposition, electron beam deposition, atomic layer deposition (ALD), electroplating, electrodeposition, spin coating, spray pyrolysis, molecular beam epitaxy (MBE), or any suitable deposition method. In some embodiments, the deposition method comprises CVD. In some embodiments, the deposition method comprises PVD. In some embodiments, the deposition method comprises sputtering. In some embodiments, the deposition method comprises evaporation deposition. In some embodiments, the deposition method comprises thermal deposition. In some embodiments, the deposition method comprises electron beam deposition. In some embodiments, the deposition method comprises ALD. In some embodiments, the deposition method comprises electroplating. In some embodiments, the deposition method comprises electrodeposition. In some embodiments, the deposition method comprises spin coating. In some embodiments, the deposition method comprises spray pyrolysis. In some embodiments, the deposition method comprises MBE. In some embodiments, generating the second layer in (c) comprises attaching the second layer using an attachment method. In some embodiments, the attachment method comprises one or more of fusion bonding, direct bonding, adhesive bonding, anodic bonding, eutectic bonding, metal diffusion bonding, or any other suitable bonding method. In some embodiments, the attachment method comprises fusion bonding. In some embodiments, the attachment method comprises direct bonding. In some embodiments, the attachment method comprises adhesive bonding. In some embodiments, the attachment method comprises anodic bonding. In some embodiments, the attachment method comprises eutectic bonding. In some embodiments, the attachment method comprises metal diffusion bonding. In some embodiments, the allotrope of carbon is diamond. In some embodiments, the allotrope of carbon is natural diamond. In some embodiments, the allotrope of carbon is synthetic diamond. In some embodiments, the allotrope of carbon is polycrystalline diamond. In some embodiments, the allotrope of carbon is composite diamond. In some embodiments, the allotrope of carbon is diamond-like carbon. In some embodiments, the allotrope of carbon is graphite. In some embodiments, the allotrope of carbon is graphene.

Disclosed herein is a heat dissipating circuit board comprising, a first layer of the heat dissipating circuit board, a first metal layer on the first layer, and a second layer of the heat dissipating circuit board, wherein the second layer comprises a plurality of vias in a pattern corresponding to the first metal layer, and wherein the second layer comprises an allotrope of carbon.

In some embodiments, the first metal layer comprises a patterned metal layer. In some embodiments, the plurality of vias is patterned according to a pattern of the first metal layer. In some embodiments, the first layer is a printed circuit board. In some embodiments, the through holes or vias are formed in the second circuit board layer before the second circuit board layer is overlaid on the first metallized layer. In some embodiments, the through holes or vias are formed in the second circuit board layer after the second circuit board layer is overlaid on the first metallized layer. In some embodiments, the plurality vias comprise a through via, a blind via, or buried via. In some embodiments, the heat dissipating circuit board further comprises a second metal layer patterned on a side of the second layer of the heat dissipating circuit board opposite the first metal layer. In some embodiments, the first metal layer further comprises a first intermediate layer disposed between the first metal layer and the first layer of the heat dissipating circuit board. In some embodiments, the first intermediate layer comprises an electrically conductive material. In some embodiments, the first layer of the high temperature circuit board comprises an electrically insulative material with high thermal conductivity (HTc layer). In some embodiments, the first layer has a first side and a second side opposite the first side, and the first metal layer is on the first side of the first layer. In some embodiments, the heat dissipating circuit board further comprises a second metal layer patterned above the second layer of the heat dissipating circuit board. In some embodiments, the second metal layer further comprises a second intermediate layer disposed between said second metal layer and said second side of the second layer of the heat dissipating circuit board. In some embodiments, the second intermediate layer comprises an electrically conductive material. In some embodiments, the heat dissipating circuit board further comprises a second metal layer patterned over the second layer of the heat dissipating circuit board. In some embodiments, the heat dissipating circuit board further comprises a third layer of the heat dissipating circuit board over the second metal layer, wherein the third layer comprises a second plurality of vias in a pattern corresponding to the second metal layer, and wherein the second layer comprises an allotrope of carbon. In some embodiments, the second plurality of vias comprises a through via, a blind via, or buried via. In some embodiments, the heat dissipating circuit board further comprises a heat source attached to the heat dissipating circuit board. In some embodiments, the heat source comprises one or more of a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source. In some embodiments, the heat source comprises a transistor. In some embodiments, the heat source comprises a FET. In some embodiments, the heat source comprises a MOSFET. In some embodiments, the heat source comprises a semiconductor chip. In some embodiments, the heat source comprises a semiconductor die. In some embodiments, the heat source comprises a CPU. In some embodiments, the heat source comprises a microcontroller. In some embodiments, the heat source comprises a GPU. In some embodiments, the heat source comprises a graphics chip. In some embodiments, the heat source comprises a chipset. In some embodiments, the heat source comprises an SoC. In some embodiments, the heat source comprises a capacitor. In some embodiments, the heat source comprises a resistor. In some embodiments, the heat source comprises a regulator. In some embodiments, the heat source comprises a rectifier. In some embodiments, the heat source comprises a diode. In some embodiments, the heat source comprises a transducer. In some embodiments, the heat source comprises an inductor. In some embodiments, the heat dissipating circuit board further comprises a heat dissipative structure attached to the heat dissipating circuit board. In some embodiments, the heat dissipative structure comprises one or more of a heat sink, a cooling pad, a liquid cooling device, a heat pipe, a vapor chamber, a phase-change cooling device, a thermoelectric cooling device, a Peltier cooling device, a heat spreader, or any suitable heat dissipative structure. In some embodiments, the heat dissipative structure comprises a heat sink. In some embodiments, the heat dissipative structure comprises a cooling pad. In some embodiments, the heat dissipative structure comprises a liquid cooling device. In some embodiments, the heat dissipative structure comprises a heat pipe. In some embodiments, the heat dissipative structure comprises a vapor chamber. In some embodiments, the heat dissipative structure comprises a phase-change cooling device. In some embodiments, the heat dissipative structure comprises a thermoelectric cooling device. In some embodiments, the heat dissipative structure comprises a Peltier cooling device. In some embodiments, the heat dissipative structure comprises a heat spreader. In some embodiments, the heat source is attached to the heat dissipating circuit board by a metal pad formed on the heat dissipating circuit board. In some embodiments, the metal pad is thermally connected to the second layer of the heat dissipating circuit board. In some embodiments, the heat dissipative structure is attached to the heat dissipating circuit board by a metal pad formed on the heat dissipating circuit board. In some embodiments, the metal pad is thermally connected to the second layer of the heat dissipating circuit board. In some embodiments, the second layer is overlaid using a deposition method. In some embodiments, the deposition method comprises one or more of chemical vapor deposition (CVD), physical vapor deposition (PVD), sputtering, evaporation deposition, thermal deposition, electron beam deposition, atomic layer deposition (ALD), electroplating, electrodeposition, spin coating, spray pyrolysis, molecular beam epitaxy (MBE), or any suitable deposition method. In some embodiments, the deposition method comprises CVD. In some embodiments, the deposition method comprises PVD. In some embodiments, the deposition method comprises sputtering. In some embodiments, the deposition method comprises evaporation deposition. In some embodiments, the deposition method comprises thermal deposition. In some embodiments, the deposition method comprises electron beam deposition. In some embodiments, the deposition method comprises ALD. In some embodiments, the deposition method comprises electroplating. In some embodiments, the deposition method comprises electrodeposition. In some embodiments, the deposition method comprises spin coating. In some embodiments, the deposition method comprises spray pyrolysis. In some embodiments, the deposition method comprises MBE. In some embodiments, the second layer is overlaid using an attachment method. In some embodiments, the attachment method comprises one or more of fusion bonding, direct bonding, adhesive bonding, anodic bonding, eutectic bonding, metal diffusion bonding, or any other suitable bonding method. In some embodiments, the attachment method comprises fusion bonding. In some embodiments, the attachment method comprises direct bonding. In some embodiments, the attachment method comprises adhesive bonding. In some embodiments, the attachment method comprises anodic bonding. In some embodiments, the attachment method comprises eutectic bonding. In some embodiments, the attachment method comprises metal diffusion bonding. In some embodiments, the second layer comprises diamond. In some embodiments, the allotrope of carbon is diamond. In some embodiments, the allotrope of carbon is natural diamond. In some embodiments, the allotrope of carbon is synthetic diamond. In some embodiments, the allotrope of carbon is polycrystalline diamond. In some embodiments, the allotrope of carbon is diamond-like carbon. In some embodiments, the allotrope of carbon is graphite. In some embodiments, the allotrope of carbon is graphene.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1A and FIG. 1B provide non-limiting examples of Printed Circuit Board (PCB) fabrication using co-fired ceramics, in accordance with some embodiments;

FIG. 2 provides a non-limiting example of a heat dissipating circuit board (HTcCB), in accordance with some embodiments;

FIG. 3 provides a non-limiting example of additional layers of a heat dissipating circuit board (HTcCB), in accordance with some embodiments;

FIG. 4 provides a non-limiting example of elements attached to a heat dissipating circuit board (HTcCB), in accordance with some embodiments;

FIG. 5 provides a non-limiting example of a method for forming a heat dissipating circuit board (HTcCB), in accordance with some embodiments; and

FIG. 6 provides a non-limiting example of a schematic of forming a heat dissipating circuit board (HTcCB), in accordance with some embodiments.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

It shall be understood that different aspects of the invention can be appreciated or modified individually, collectively, or in combination with each other. Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

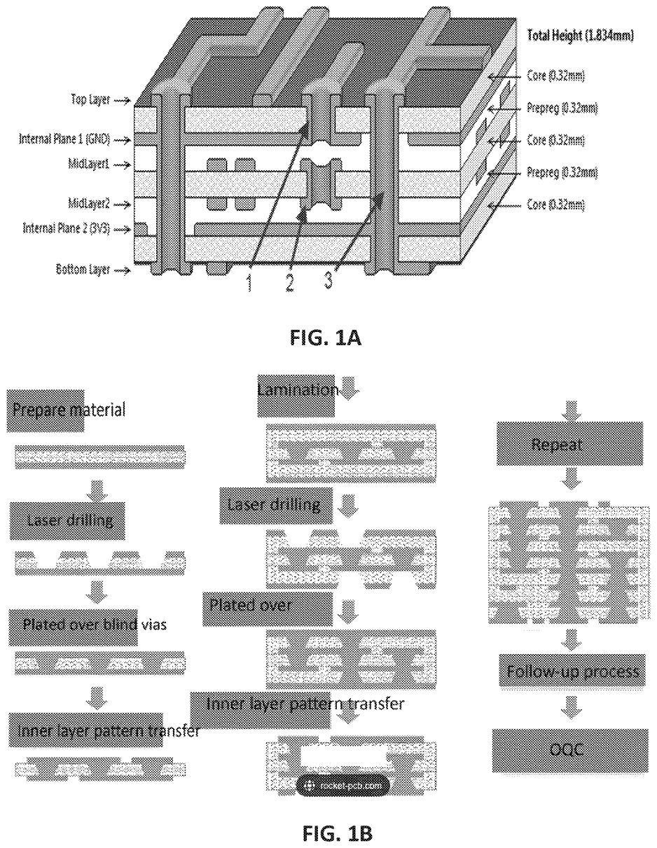

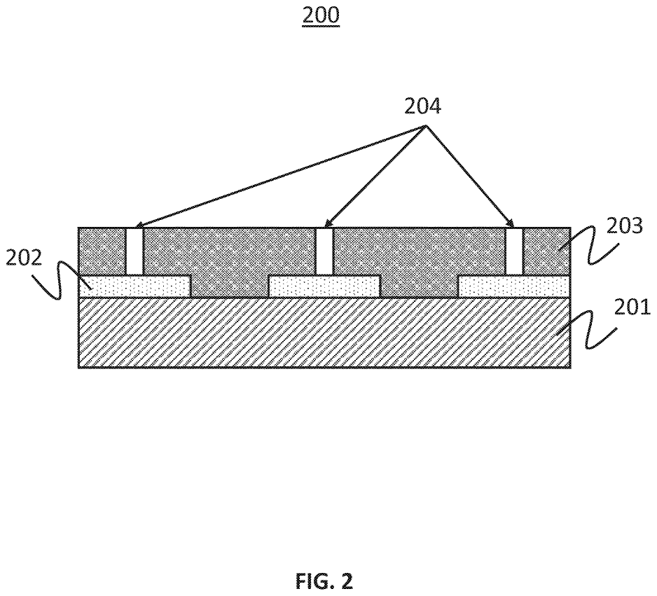

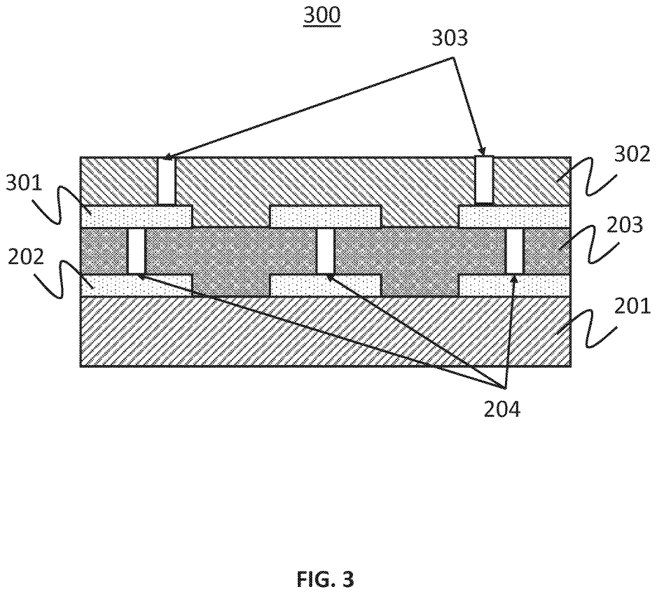

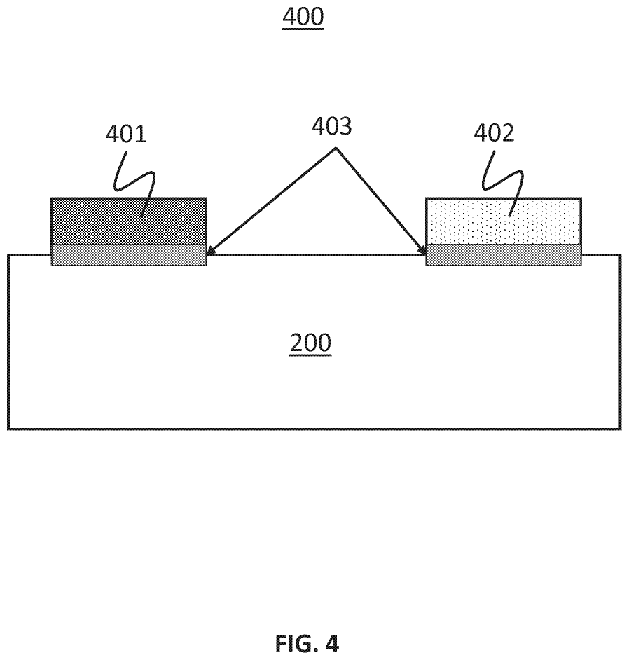

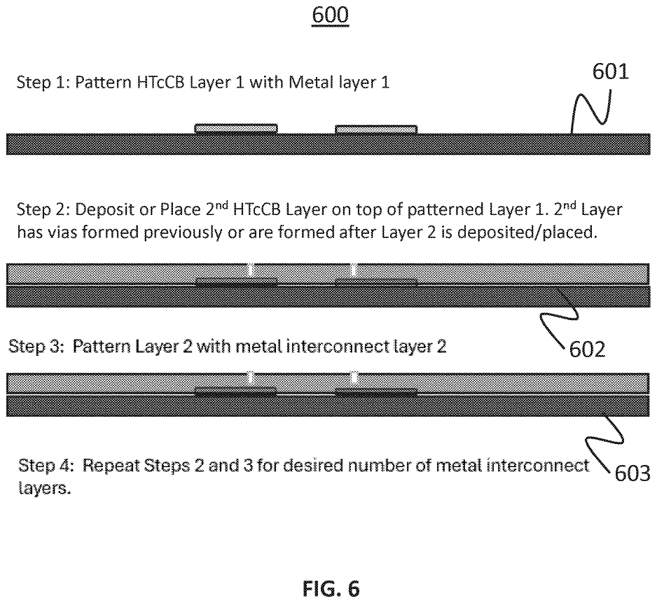

Elements as shown in FIG. 1A, FIG. 1B, FIG. 2, FIG. 3, FIG. 4, and FIG. 6 are not to scale, and may include, for example, magnified or exaggerated thicknesses and surface roughness.

### Overview

Many modern devices, such as computers, smartphones, tablets, medical equipment, vehicle systems, gaming consoles, and numerous other digital devices function at least in part using very dense electrical circuits attaching electronic components to Printed Circuit Boards (PCBs). In many cases, the dense packing of the circuitry on these PCBs is employed to deliver high performance from a small form factor. Achieving such high-performance from a small form factor is a driving force in electronics innovation.

In many cases, the very dense electrical circuits on the PCBs are prone to heat buildup, which limits performance, and can lead to degradation of the circuits printed on the PCBs and the components attached to the PCBs. PCBs may comprise co-fired ceramics or silicon as a substrate for patterning metal connections onto. Non-limiting examples of PCB fabrication using co-fired ceramics are provided in FIG. 1A and FIG. 1B, in accordance with some embodiments. In many cases, these co-fired ceramic materials may not be good thermal conductors. Heat generated by the components attached to the PCBs may travel through this low thermal conducting layer before it can be dissipated, often leading to overheating of components due to the poor heat flow. As innovation continues to drive the need for higher performance from smaller form factors for PCBs, removing heat from such PCBs may be important.

Recognized herein is the need for systems and methods for heat dissipating circuit boards with high thermal conductivity.

### Examples of High Thermal Conductivity Circuit Boards

To remove heat from such PCBs, herein is provided methods and systems for incorporating one or more High Thermal Conductivity (HTc) layers into a high thermal conductivity circuit board (HTcCB). In some cases, a heat dissipating circuit board herein is a HTcCB.

A non-limiting example of a HTcCB 200 is provided in FIG. 2, in accordance with some embodiments. In some cases, a HTcCB 200 herein comprises a first layer of the HTcCB 201, a first metal layer 202 on the first layer, and a second layer of the HTcCB 203 overlaid on the first metal layer, wherein the second layer comprises a plurality of vias 204 in a pattern corresponding to the first metal layer 202.

In some cases, one or more layers of the HTcCB 200 comprises a high thermal conductivity (HTc) layer. In some cases, one or more layers of the HTcCB 200 comprises a diamond allotrope. In some cases, the first layer 201 comprises a HTc layer, herein. For example, the first layer 201 may comprise diamond. In some cases, the second layer 203 comprises an HTc layer, herein. For example, the second layer 203 may comprise diamond.

### Examples of High Thermal Conductivity (HTc) Layers

HTc layers comprise layers of material which are thermally conductive but electrically insulative. HTc layers may comprise silicon carbide (SiC). HTc layers may comprise allotropes of carbon. HTc layers may comprise diamond. HTc layers may comprise natural diamond. HTc layers may comprise synthetic diamond. HTc layers may comprise composite diamond. HTc layers may comprise diamond-like carbon. HTc layers may comprise graphene. HTc layers may comprise graphite. HTc layers may comprise aluminum nitride (AlN). HTc layers may comprise any other ceramic material which is thermally conductive but electrically insulative. HTc layers may comprise any other polymeric material which is thermally conductive but electrically insulative. For example, the first layer 201 may be a polymer layer. HTc layers may comprise any other compound which is thermally conductive but electrically insulative.

In some cases, HTc layers herein may comprise a substrate layer. For example, the first layer 201 may be a substrate layer. A substrate may be any substance upon which a structure (e.g., HTcCB) is formed. The substrate may comprise a foundation for the fabrication of electronic devices, such as transistors, diodes, and integrated circuits. The substrate may be a supporting component upon which or within which the elements of a HTcCB device are fabricated or attached. The substrate may comprise a solid material such as a semiconductor or an insulator. Substrate materials may comprise one or more of, for example, carbon, aluminum, gallium, silicon, germanium, arsenic, thallium, cadmium, tellurium, selenium, or alloy or allotrope thereof, or an oxide or nitride thereof. The substrate may be a carbon-containing substrate or a semiconductor-containing substrate. The substrate may include one or more chemical dopants, for example, nitrogen, phosphorous, boron or indium. Substrate materials may comprise one or more of, for example, diamond, synthetic diamond, silicon (Si), silicon dioxide (SiO₂), silicon carbide (SiC), aluminum oxide (Al₂O₃), sapphire, aluminum nitride (AlN), scandium aluminum nitride (ScAlN), germanium, gallium arsenide, gallium nitride (GaN), or indium phosphide (InP), indium nitride (InN), aluminum gallium nitride (AlGaN), indium gallium nitride (InGaN), indium aluminum nitride (InAlN), zinc oxide (ZnO), for example. The substrate may include carbon-containing materials such as diamond, synthetic diamond, diamond-like carbon (DLC), diamond nanoparticles (e.g., nanodiamond), graphite, graphene, etc. The substrate may include a material having a thermal conductivity (W/mk). Thermal conductivity, or the measurement of the ability of a material to conduct heat, may be measured and quantified as an average value. For example, a substrate may include a material having a thermal conductivity equal to or greater than about 1,000 W/mK (e.g., in at least a single dimension). The average thermal conductivity of such substrate may be greater than at least about 500 W/mK, 1,000 W/mK, 1,500 W/mK, 2,000 W/mK, 2,500 W/mK, 3,000 W/mK or greater. The average thermal conductivity may be within a range from about 500 W/mK to about 2,000 W/mK. The average thermal conductivity may be within a range from about 500 W/mK to about 3,000 W/mK. The average thermal conductivity may be within a range from about 1,500 W/mK to about 2,500 W/mK. Such materials may be high-thermal conductivity materials. The substrate may include a wide-bandgap semiconductor. The substrate material may be single crystalline, polycrystalline, amorphous or a combination thereof. The substrate may comprise a buffer layer. The substrate may comprise a barrier layer. The substrate may comprise a buffer layer disposed adjacent to the barrier layer. An intermediate layer may be disposed between the buffer layer and the barrier layer. The buffer layer may comprise a wide-bandgap semiconductor. The buffer layer may comprise a Group III element and a Group V element. The barrier layer may comprise a wide-bandgap semiconductor. The barrier layer may comprise a Group III element and a Group V element. The barrier layer may comprise a source region and a drain region. The buffer layer and the barrier layer may include a channel between the source region and the drain region.

Active layers of a HTcCB may be epitaxially grown on a substrate. In some cases, the substrate may be of the same family of materials as the active layers of the electronic devices or heat sources deposited thereon. Electronic materials for device fabrication may be realized by attaching the active layers to substrates comprising materials having crystalline structures and material combinations different from the active layer. Examples of ways to attach electrical components and heat sources to substrates having different crystal structures can include direct-bonding or direct growth using transition layer(s) to bridge different lattice structures. Alternatives to bonding and die-attachment may include the use of selective area deposition (SAD).

The substrate may have various functions, for example, (i) mechanical support; (ii) electrical conductivity that can be used to connect the active layers to the bottom of the chip; (iii) electrical isolation with low dielectric losses that can be used in high-frequency devices and surface waveguides where electric fields penetrate into the substrate; and (iv) high thermal conductivity with or without associated electrical conductivity.

A substrate may comprise a thickness of at least about 1 micron, at least about 10 microns, at least about 50 microns, at least about 100 microns, at least about 1 millimeter or greater. A substrate may comprise a thickness of at least 1 millimeter of diamond. A substrate may comprise a thickness of diamond within a range from about 1 micron to about 1 millimeter, within a range from about 10 microns to about 1 millimeter, within a range from about 50 microns to about 1 millimeter or within a range from about 100 microns to about 500 microns. A substrate may comprise a thickness of about 100 microns, about 105 microns, about 110 microns, about 125 microns, about 150 microns, or greater.

A substrate may comprise a comprise a two-dimensional electron gas layer (2DEG layer), which may be embedded within a layered structure. A 2DEG layer may be embedded within a buffer layer. A 2DEG layer may be proximate to an interface between a barrier layer and a buffer layer. A 2DEG layer may have a width of less than 50 nm, less than 10 nm, or less than 5 nm. A 2DEG layer, for example, may be no further than 150 nm, no further than 250 nm, no further than 500 nm, no further than 750 nm, no further than 1 micron, or no further than 100 microns, from an interface between a layered structure and a carbon-containing substrate (e.g., diamond substrate).

HTc layers may comprise epitaxially grown, sliced, laser exfoliated, layers. HTc layers may comprise portions which are single crystal, described herein. HTc layers may comprise portions which are polycrystalline, described herein. HTc layers may comprise portions which are amorphous, described herein. For example, HTc layers herein may comprise polycrystalline diamond.

In some cases, a material herein may be single-crystalline. A single-crystal material may be a material in which the crystal lattice of the sample is substantially continuous or unbroken to the edges of the sample, with no or substantially no grain boundaries. The material may have a translational symmetry. In some cases, a material herein may be polycrystalline. A polycrystalline material may be a material having more than one crystal domain or orientation. A polycrystalline material may exhibit more than one crystal structure under low energy electron diffraction (LEED) microscopy. A polycrystalline material may comprise smaller crystal domains such as crystallite or paracrystalline phases. In some cases, a material herein may be amorphous. An amorphous material may be a material having no real or apparent crystalline form. An amorphous material may lack long range order. An amorphous material may not exhibit any long-range crystal structure under LEED.

HTc layers, herein, may comprise a layered structure. For example, a multi-layered HTc layer may comprise two or more HTc layers. In some cases, the two or more HTc layers may comprise the same HTc material. For example, a HTc layer may be formed by depositing a second layer of synthetic diamond on a first layer of synthetic diamond. In some cases, individual layers of the multi-layered HTc layer may undergo processing before forming the second layer. For example, the first layer of synthetic diamond of the multi-layered HTc layer may undergo etching or polishing before depositing a second synthetic diamond layer.

In some cases, the two or more HTc layers may comprise different HTc materials. For example, a HTc layer may be formed by depositing a layer of SiC on a layer of synthetic diamond. In some cases, individual layers of the multi-layered HTc layer may undergo processing before forming the second layer. For example, the synthetic diamond layer of the multi-layered HTc layer may undergo etching or polishing before depositing a SiC layer.

Etching may be a process of removing (e.g., via chemical or gas etchant) one or more layers from a wafer or substrate. A portion of the substrate may be protected from etching by the use of an etch mask, which may comprise material that resists etching. Etch mask materials may include, for example, silicon nitride, silicon dioxide, aluminum, titanium, nickel, or gold. Etching may include wet etching (e.g., using chemical etchants). Etching may include dry etching (e.g., using plasma or gas etchants), also known as plasma etching. Plasma etching may, for example, include microwave plasma etching, hydrogen plasma etching, reactive-ion etching (RIE), ion-assisted chemical vapor etching, inductively coupled plasma (ICP), transformer-coupled plasma (TCP) or capacitively coupled plasma (CCP). A plasma etcher, or etching tool, may be used to plasma etch a substrate. An etching tool may produce a plasma source (e.g., etching species) from a gas (e.g., O₂, fluorine-bearing gas) and an electric field (e.g., RF, microwave, DC). An etching species may comprise positively charged or negatively charged ions. Etching quality may be influenced in part by parameters including selectivity, uniformity, directionality, plasma density, and etching rate. Plasma density may be determined by plasma process parameters such as plasma etch power, process pressure, and gas flow rate.

A layered structure may comprise structures created from layers of materials of varying properties. A layered structure may comprise layers of the same or varying semiconductor properties. Individual layers may be single crystalline or polycrystalline. Individual layers may be amorphous. Electronic and optoelectronic devices manufactured out of layers of different semiconductor properties may be made by different growth techniques. In some cases, these growth techniques may allow for controlled growth of individual layers. In some cases, the layers may be epitaxial layers or epilayers. Each layer may be of a thickness varying from sub-nanometer to tens of microns. Each layer may be of a thickness between 1 nanometer (nm) and 50 nm, between 10 nm and 100 nm, etc. Each layer may be greater than 1 nm, 2 nm, 5 nm, greater than 10 nm, 20 nm, greater than 50 nm, greater than 100 nm, greater than 1 micron or greater. Each layer may be less than 1 micron, less than 100 nm, less than 50 nm, less than 20 nm, less than 10 nm, less than 5 nm, less than 2 nm, less than 1 nm, or less. Each layer may be atomically thin. Non-limiting examples of manufacturing techniques include molecular beam epitaxy (MBE), chemical vapor deposition (CVD), atomic layer deposition (ALD), physical vapor deposition, organo-metallic vapor-phase epitaxy, and liquid phase epitaxy.

In some cases, further layers of a HTcCB 200 may be epitaxially grown on one or more HTc layers, which may act as a substrate. In some cases, further layers of the HTcCB 200 comprise one or more epitaxial layers, described herein. In some cases, further layers of the HTcCB 200 comprise one or more intermediate layers, described herein. Examples of methods and systems for forming HTcCBs 200 comprising HTc layers, epitaxial layers, and intermediate layers are described in commonly owned United States Patent Publication No. 2024-0170362-A1, which is incorporated by reference herein in its entirety.

Epitaxial layers may comprise one or more of, for example, boron, aluminum, gallium, indium, thallium, carbon, silicon, germanium, tin, lead, nitrogen, phosphorous, arsenic, antimony, bismuth, oxygen, sulfur, selenium, tellurium, beryllium, magnesium, calcium, zinc, cadmium, scandium, and alloys and allotropes thereof or an oxide or nitride thereof. Epitaxial layers may comprise a semiconductor comprising a bond between at least one Group III element and at least one Group V element. Epitaxial layers may comprise semiconductors comprising a bond between nitrogen and at least one Group III element (e.g., boron, aluminum, gallium, indium, thallium, scandium), semiconductors comprising a bond between carbon and at least one group IV element (e.g., carbon, silicon, germanium, tin, lead), and semiconductors comprising a bond between oxygen and at least one group II element (e.g., beryllium, magnesium, calcium, zinc, cadmium). Epitaxial layers may comprise one or more wide-bandgap semiconductors. Epitaxial layers may comprise one or more of, for example, GaN, AlN, InN, AlGaN, InGaN, InAlN, ZnO, SiC, and diamond. Any of the above materials may be single-crystalline, polycrystalline, or amorphous.

In some cases, one or more layers herein are overlaid using a deposition method. For example, the second layer 203 may be overlaid on the first layer 201 by a deposition method. In another example, a second HTc layer of a multi-layered HTc layer herein may be overlaid on a first HTc layer of a multi-layer HTc layer by a deposition method.

In some cases, deposition methods herein comprise one or more of chemical vapor deposition (CVD), physical vapor deposition (PVD), sputtering, evaporation deposition, thermal deposition, electron beam deposition, atomic layer deposition (ALD), electroplating, electrodeposition, spin coating, spray pyrolysis, molecular beam epitaxy (MBE), or any suitable deposition method. In some cases, a deposition method herein comprises CVD. In some cases, a deposition method herein comprises PVD. In some cases, a deposition method herein comprises sputtering. In some cases, a deposition method herein comprises evaporation deposition. In some cases, a deposition method herein comprises thermal deposition. In some cases, a deposition method herein comprises electron beam deposition. In some cases, a deposition method herein comprises ALD. In some cases, a deposition method herein comprises electroplating. In some cases, a deposition method herein comprises electrodeposition. In some cases, a deposition method herein comprises spin coating. In some cases, a deposition method herein comprises spray pyrolysis. In some cases, a deposition method herein comprises MBE.

In some cases, one or more layers herein are overlaid using an attachment method. For example, the second layer 203 may be overlaid on the first layer 201 by an attachment method. In another example, a second HTc layer of a multi-layered HTc layer herein may be overlaid on a first HTc layer of a multi-layer HTc layer by an attachment method.

In some cases, the attachment method comprises one or more of fusion bonding, direct bonding, adhesive bonding, anodic bonding, eutectic bonding, metal diffusion bonding, or any suitable attachment method. In some cases, an attachment method herein comprises fusion bonding. In some cases, an attachment method herein comprises direct bonding. In some cases, an attachment method herein comprises adhesive bonding. For example, adhesive bonding may comprise bonding two layers using one or more polymer adhesives or epoxy adhesives such as SU-8 or benzocyclobutane (BCB). In some cases, an attachment method herein comprises anodic bonding. In some cases, an attachment method herein comprises eutectic bonding. In some cases, an attachment method herein comprises metal diffusion bonding.

In some cases, one or more additional layers of the HTcCB 200 may be mechanically connected to the HTc layer. In some cases, one or more additional layers of the HTcCB 200 may be thermally connected to the HTc layer. In some cases, one or more additional layers of the HTcCB 200 may be mechanically connected to the HTc layer using an intermediate layer. In some cases, one or more additional layers of the HTcCB 200 may be thermally connected to the HTc layer using an intermediate layer.

In some cases, the coefficient of thermal expansion of the one or more HTc layers may differ from the coefficient of thermal expansion of the one or more further layers of the HTcCB 200, producing a mismatch. In such cases, one or more intermediate layers, described herein, may be used to accommodate this mismatch in coefficients of thermal expansion. In some cases, the mismatch in coefficients of thermal expansion may be accommodated, at least in part, by the composition of the interconnect materials of the one or more intermediate layers. In some cases, the mismatch in coefficients of thermal expansion may be accommodated, at least in part, by the height of the one or more intermediate layers. In some cases, the mismatch in coefficients of thermal expansion may be accommodated, at least in part, by sandwiching the one or more further layers of the HTcCB 200 between two HTc layers.

### Examples of Metal Layers

In some cases, the HTcCB 200 comprises one or more metal layers. For example, the HTcCB 200 may comprise a first metal layer 202 on the first layer of the HTcCB 201. In some cases, a metal layer is patterned onto a side of an HTc layer, herein. For example, the first metal layer 202 may comprise a patterned metal layer. In some cases, a metal layer is patterned onto a side of the HTc layer using photolithography. In some cases, a metal layer is patterned onto a side of the HTc layer using circuit board photolithography. In some cases, a metal layer is patterned onto a side of the HTc layer using metal patterning techniques. In some cases, a metal layer is patterned onto a side of the HTc layer using circuit board photolithography and metal patterning techniques. In some cases, additional metal layers may be patterned on top of existing layers.

In some cases, a patterned metal layer herein may comprise one or more metal patterning techniques, such as photolithography, circuit board lithography, soft lithography, laser processing, liquid metal deposition, direct writing deposition, stencil deposition, physical stencil transfer, physical mask transfer, and any suitable metal patterning technique.

In some cases, the one or more metal patterning layers comprise electrical connections. In some cases, the one or more metal patterning layers comprise one or more metal interconnect layers.

In some cases, a metal layer is patterned onto a side of the one or more additional layers of the HTcCB 200. A non-limiting example of additional layers of a HTcCB is provided in FIG. 3, in accordance with some embodiments. For example, a second metal layer 301 may be patterned on a side of the second layer 203 of the HTcCB 200 opposite the first metal layer 202. In some cases, a metal layer is patterned onto a side of the one or more additional layers of the HTcCB 200 using photolithography. In some cases, a metal layer is patterned onto a side of the one or more additional layers of the HTcCB 200 using circuit board photolithography. In some cases, a metal layer is patterned onto a side of the one or more additional layers of the HTcCB 200 using metal patterning techniques. In some cases, a metal layer is patterned onto a side of the one or more additional layers of the HTcCB 200 using circuit board photolithography and metal patterning techniques. In some cases, additional metal layers may be patterned on top of existing layers.

In some cases, a metal layer may be used to form a Schottky contact. For example, the metal layer 202 or 301 may be used to form a Schottky contact. A Schottky contact may be a metal-semiconductor interface with a non-zero contact resistance, measured relative to the resistance of the semiconductor. The contact may comprise an energetic barrier between states of the semiconductor and states of the metal which barrier may be non-zero. The contact may be a rectifying contact, e.g., a Schottky barrier. In some examples, devices may include one or more dielectric or insulating material layers, for example, under a gate contact. Such devices may comprise Metal-Insulator-Semiconductor Field Effect Transistors (MISFETs).

In some cases, layers of the HTcCB include an interface. For example, a metal layer used to form a Schottky contact may have a metal-semiconductor interface. An interface may be a surface forming a common boundary between two different materials, for example, materials having differing crystalline structures, differing material combinations, or differing material properties. An interface may refer to a location where two different materials come into contact with one another. An interface may also refer to the atoms of a first material combining with the atoms of a second material at a location or at a boundary, for example, without the presence of atoms of a third material. An interface may be a surface forming a common boundary between semiconductor and diamond. An interface can be a location where diamond atoms contact atoms of a wide-bandgap semiconductor. A compound substrate of the present disclosure may include a single interface. In some examples, such compound substrate may not include more than one interface.

In some cases, the HTcCB 200 comprises one or more intermediate layers between layers of the structure. In some cases, the intermediate layers may be metal layers, such as copper, aluminum, gold, nickel, or titanium. In some cases, the intermediate layers may be thermally conductive layers. In some cases, the intermediate layers may be electrically conductive layers. In some cases, the intermediate layers may be an HTc layer, herein. In some cases, the intermediate layers may be a polymer layer. In some cases, the intermediate layer may be a ceramic layer. In some cases, the intermediate layer may be used to bond the one or more layers together. For example, an intermediate layer comprising metal may be used to bond two layers together using metal diffusion bonding.

In some cases, the HTcCB 200 comprises generating the second layer of the heat dissipating circuit board over the first metal layer 202. In some cases, the first metal layer 202 comprises a first intermediate layer disposed between the first metal layer 202 and the first layer of the HTcCB 201. In some cases, the first layer of the HTcCB 201 has a first side and a second side opposite the first side, wherein the first metal layer 202 is patterned on the first side of the first layer 201. In some cases, the heat dissipating circuit board comprises a second metal layer 301 patterned above the second layer of the HTcCB 203. In some cases, the second metal layer 301 comprises a second intermediate layer disposed between the second metal layer 303 and the second side of the second layer of the HTcCB 202.

In some cases, the first intermediate layer comprises an electrically conductive material. In some cases, the second intermediate layer comprises an electrically conductive material.

An intermediate layer may be a material layer disposed between two material layers, for example, between two layers of materials having similar or varying properties. Intermediate layers may comprise single crystalline, polycrystalline, or amorphous materials. Intermediate layers may comprise wide-bandgap semiconductors, as described herein. Intermediate layers may comprise carbon-containing materials as described herein. Individual layers surrounding an intermediate layer may comprise materials having different lattice-constants or different lattice structures. Individual layers surrounding an intermediate layer may comprise materials having different thermal conductivities and/or different sheet resistivities. An intermediate layer may comprise an interface or interface layer between two material layers. An intermediate layer may have a thickness from about sub-nanometer to tens of microns. An intermediate layer may have a thickness from about 20 nm to about 2,000 nm. An intermediate layer may have a thickness between about 1 nm and 50 nm, between 10 nm and 100 nm, etc. An intermediate layer may have a thickness greater than about 1 nm, 2 nm, 5 nm, greater than 10 nm, 20 nm, greater than 50 nm, greater than 100 nm, greater than 1 micron or greater. An intermediate layer may have a thickness less than about 1 micron, less than 100 nm, less than 50 nm, less than 20 nm, less than 10 nm, less than 5 nm, less than 2 nm, less than 1 nm, or less. An intermediate layer may have a thickness from about 1 nm to about 150 nm, about 150 nm or greater than 150 nm. An intermediate layer may be thinned by a method such as mechanical polishing or etching.

An intermediate layer may comprise an anchoring layer. An intermediate layer may comprise an immobilizing layer. An intermediate layer may comprise a tacking layer. An anchoring layer may assist in anchoring diamond seeds to a material layer, for example, anchoring a layer of diamond seeds to a semiconductor or dielectric-containing material layer.

In some cases, the HTcCB includes one or more immobilizing layers. An immobilizing layer may assist in immobilizing a layer of diamond seeds over a surface of a semiconductor-containing material layer. A tacking layer may assist in tacking a layer of diamond seeds to a surface of a semiconductor or dielectric-containing material layer. In some examples, the diamond seeds may be immobilized, anchored, or tacked to a semiconductor surface, in part, through Van der Waals bonding between the diamond seeds and the semiconductor surface. In some examples, the diamond seeds may be immobilized, anchored, or tacked to a dielectric or semiconductor surface, in part, through adhesion of the intermediate layer to the dielectric or semiconductor surface.

An intermediate layer may comprise a transition layer between two material layers or two substrates. In some examples, a transition layer may bridge a first lattice structure (e.g., first lattice constant) of a first material layer to a second lattice structure (e.g., second lattice constant) of a second material layer, for example, within a layered semiconductor structure. One or more transition layers may be used to accommodate for a change in the lattice constants and help absorb dislocations between two material layers or substrates.

An intermediate layer may comprise a nucleation layer. A nucleation layer or nucleating layer may be a material layer that assists in starting the growth or formation of another layer of material or stoichiometry. Nucleating layer materials can include semiconductors, for example, wide-bandgap semiconductors. Nucleating materials can include silicon, silicon nitride (SiN), silicon carbide (SiC), or other materials that may aid in the nucleation of synthetic diamond. Nucleating materials can include, for example, InGaN, InAlN, AlN, ScAlN or derivatives thereof. Nucleating layer materials can assist in preventing etching or damage to an underlying semiconductor material or substrate. Nucleating materials can be amorphous or polycrystalline. The presence of a nucleating layer may create multiple interfaces between a layered semiconductor structure and a substrate. Multiple interfaces can include, for example, (i) a first interface between a diamond substrate and a nucleating layer and (ii) a second interface between the nucleating layer and a layered semiconductor structure.

Nucleating layer(s) may be disposed between two material layers or substrates, such as two material layers having similar or varying properties. A nucleating layer may have similar properties to a material to which the nucleating layer assists in the growth of. Nucleating layers may be used in nucleating diamond on semiconductor-containing structures. Nucleating layers may be protective layers that protect such structures from damage. Such structures may include one or more nucleating layers disposed between a semiconductor-containing material and diamond. A nucleating layer may be an individual layer that is independent from a semiconductor-containing structure and may be disposed on a surface of such structure. In some cases, a nucleating layer may be nucleation material that is added to a later stage of growth of such structure (e.g., later stage of epitaxial growth), in which case the nucleation material may not be an independent layer but may be integrated into the structure near a surface (e.g., top surface). A diamond growth process can include a nucleation phase in which a nucleating layer and a set of diamond-growth conditions can enhance diamond nucleation on a host substrate. Diamond-growth conditions can include conditions within a vacuum chamber, for example, in the case of vapor deposition (e.g., CVD).

In some cases, the HTcCB 300 further comprises a second metal layer 301 patterned over the second layer of the heat dissipating circuit board 203. In some cases, the HTcCB 300 further comprises a third layer of the HTcCB 302 over the second metal layer 301.

In some cases, the first layer 201 is an allotrope of carbon. For example, the first layer 201 may be diamond. For example, the first layer 201 may be synthetic diamond. For example, the first layer 201 may be natural diamond. For example, the first layer 201 may be polycrystalline diamond. For example, the first layer 201 may be diamond-like carbon. For example, the first layer 201 may be graphite. For example, the first layer 201 may be graphene.

In some cases, the second layer 203 is an allotrope of carbon. For example, the second layer 203 may be diamond. For example, the second layer 203 may be synthetic diamond. For example, the second layer 203 may be natural diamond. For example, the second layer 203 may be polycrystalline diamond. For example, the second layer 203 may be diamond-like carbon. For example, the second layer 203 may be graphite. For example, the second layer 203 may be graphene.

In some cases, the third layer 302 is an allotrope of carbon. For example, the third layer 302 may be diamond. For example, the third layer 302 may be synthetic diamond. For example, the third layer 302 may be natural diamond. For example, the third layer 302 may be polycrystalline diamond. For example, the third layer 302 may be diamond-like carbon. For example, the third layer 302 may be graphite. For example, the third layer 302 may be graphene.

In some cases, one or more layers of the HTcCB may be a printed circuit board (PCB). For example, the first layer 201 may be a PCB. For example, the second layer 203 may be a PCB. For example, the third layer 302 may be a PCB. In some cases, one or more layers of the HTcCB may be a PCB layer, where HTc layers are added to promote heat dissipation from the one or more PCB layers. In some cases, additional features such as metal pads or other thermally conductive features may be included in the one or more PCB layers to promote heat dissipation from the one or more PCB layers to the one or more HTc layers of the HTcCB.

### Examples of Vias

In some cases, layers of a HTcCB, herein, may comprise additional features to create electrical connections between layers, such as through-holes or vias. A non-limiting example of a plurality of vias 204 in the second layer of the HTcCB 200 are provided in FIG. 2, in accordance with some embodiments. In some cases, the plurality of vias 204 is provided in a pattern corresponding to the first metal layer 202. For example, the plurality of vias 204 may be patterned according to a pattern of the first metal layer 202. In some cases, there is a one-to-one correspondence between through-holes or vias on an additional layer of the HTcCB, and features of a patterned metal layer herein. In some cases, the through-holes or vias of additional layers of the HTcCB correspond to at least a portion of the features of a patterned metal layer of the HTcCB, herein.

In some cases, the first plurality of vias 204 comprises a through via, a blind via, or a buried via. In some cases, the first plurality of vias 204 comprises a through via. In some cases, the first plurality of vias 204 comprises a blind via. In some cases, the first plurality of vias 204 comprises a buried via.

In some cases, further layers of a HTcCB, herein, may comprises additional features for creating electrical connections between layers. A non-limiting example of multiple pluralities of vias 204 and 303 in a HTcCB 300 is provided in FIG. 3, in accordance with some embodiments. In some cases, the second plurality of vias 303 are provided in a pattern corresponding to the second metal layer 301. In some cases, there is a one-to-one correspondence between through-holes or vias on an additional layer of the HTcCB, and features of a patterned metal layer herein. In some cases, the through-holes or vias of additional layers of the HTcCB correspond to at least a portion of the features of a patterned metal layer of the HTcCB, herein.

In some cases, the second plurality of vias 303 comprises a through via, a blind via, or a buried via. In some cases, the second plurality of vias 303 comprises a through via. In some cases, the second plurality of vias 303 comprises a blind via. In some cases, the second plurality of vias 303 comprises a buried via.

In some cases, these through-holes or vias may be formed in an additional layer of the HTcCB prior to the layer being overlaid. For example, the plurality of vias 204 may be formed in the second layer 203 prior to the second layer 203 being overlaid on the first layer 201. For example, the second plurality of vias 303 may be formed in the third layer 302 prior to the third layer 302 being overlaid on the second layer 203. In some cases, these through-holes or vias may be formed in an additional layer of the HTcCB after the layer is overlaid. For example, the plurality of vias 204 may be formed in the second layer 203 after the second layer 203 is overlaid on the first layer 201. For example, the second plurality of vias 303 may be formed in the third layer 302 after the third layer 302 is overlaid on the second layer 203.

In some cases, these features, such as the plurality of vias 204 and 303, may further comprise electrically conductive material. For example, the plurality of vias 204 and 303 may comprise a conductive coating. For example, the plurality of vias 204 and 303 may comprise a conductive filling. For example, the plurality of vias 204 and 303 may comprise a metal coating. For example, the plurality of vias 204 and 303 may comprise a metal filling. For example, the plurality of vias 204 and 303 may comprise a gold coating. For example, the plurality of vias 204 and 303 may comprise a gold filling. For example, the plurality of vias 204 and 303 may comprise a copper coating. For example, the plurality of vias 204 and 303 may comprise a copper filling. For example, the plurality of vias 204 and 303 may comprise a silver coating. For example, the plurality of vias 204 and 303 may comprise a silver filling. For example, the plurality of vias 204 and 303 may comprise any suitable coating to promote electrical connection between layers of the HTcCB. For example, the plurality of vias 204 and 303 may comprise any suitable filling to promote electrical connection between layers of the HTcCB.

In some cases, the one or more patterned metal layers 202 or 301 are connected to the one or more through-holes or vias of a separate layer. In some cases, the one or more patterned metal layers 202 or 301 are connected to the one or more through-holes or vias of a separate layer using metal bump processing. In some cases, the one or more patterned metal layers 202 or 301 are connected to the one or more through-holes or vias of a separate layer using Cu—Cu bump processing. In some cases, the one or more patterned metal layers 202 or 301 are connected to the one or more through-holes or vias of a separate layer using Ag—Ag bump processing. In some cases, the one or more patterned metal layers 202 or 301 is connected to the one or more through-holes or vias of a separate layer using Au-Au bump processing. In some cases, the one or more patterned metal layers 202 or 301 is connected to the one or more through-holes or vias of a separate layer using metal-metal bump processing. In some cases, the one or more patterned metal layers 202 or 301 is connected to the one or more through-holes or vias of a separate layer using metal alloy-metal alloy bump processing. In some cases, the one or more patterned metal layers 202 or 301 are connected to the one or more through-holes or vias of a separate layer using any suitable process to establish electrical connection between the through-holes or vias and the features of the one or more patterned metal layers.

Examples of methods and systems for forming conductive features, such as the plurality of vias 204 and 303, are described in commonly owned United States Patent Publication No. 2023-0420333-A1 which is incorporated by reference herein in its entirety.

A substrate feature or feature, such as the plurality of vias 204 and 303 herein, may include vertical interconnection access (via), channel, singulation trench, die street or street in a substrate, for example. A via may be an electrical connection disposed between layers in a substrate, such as a layered semiconductor-containing structure or a wafer. A via may couple a first layer of the substrate to a second layer of the substrate, a first device or circuit to second device or circuit, or to an antenna, or other component, for example. A via may couple a top or front side of a substrate to a bottom or back side of the substrate. A via may couple a via pad on a first side of the substrate to a metal layer on a second side of the substrate, for example, to provide electrical ground to a device disposed on or within the substrate or a layered structure.

A feature, such as the plurality of vias 204 and 303 herein, may comprise a hollow region within a substrate. A hollow region in a substrate, for example, may be generated at least in part by etching a portion of a semiconductor structure, for example, a layered structure. A hollow region may be generated at least in part by etching a portion of a structure that comprises substrate material. Etching substrate material may result in removal of the material. The hollow region may continue through more than one layer of the substrate, including more than one material.

A feature, such as the plurality of vias 204 and 303 herein, may also comprise a hollow region in a substrate, including one or more substrate layers, that may be plated with an electrically conductive material, such as a metal. Such features may communicatively couple two or more layers of the substrate. A plating within a feature may have a thickness of less than or equal to about 4 microns, at least 1 micron, at least 4 microns, at least 5 microns, at least 6 microns, at least 12 microns, at least 15 microns, or greater. A plating within a feature may have a thickness within a range from about 1 micron to about 4 microns, from about 4 microns to about 6 microns, from about 6 microns to about 12 microns, from about 12 microns to about 15 microns, or greater.

A feature, such as the plurality of vias 204 and 303 herein, may comprise a portion of a semiconductor structure. A semiconductor structure may, for example, be a layered structure or a wafer. A feature may comprise, for example, a singulation feature (e.g., singulation trench or a die street). A feature may comprise an edge of a semiconductor structure, such as an edge of a die after dicing of a wafer. At least a portion of a feature may be cut away from the wafer during a dicing process. In some examples, after a feature is cut away, an edge of a die may be left with at least a portion of the feature. For example, an edge of a die may be left with at least a portion of the feature comprising a material. A feature may comprise a semiconductor material. A feature may comprise silicon. A feature may comprise a material having an average value of thermal conductivity equal to or greater than about 1,000 W/mK. A feature may comprise a material having a plurality of crystals (e.g., crystal grains). Each of the plurality of crystal grains may have an average crystal grain diameter from about 10 nm to about 2,000 nm. In some examples, at least a portion of the plurality of crystal grains is disposed a distance of less than or equal to about 100 microns from a surface of a feature. At least a portion of the plurality of crystal grains may be disposed a distance of less than or equal to about 60 microns, less than or equal to about 25 microns, less than or equal to about 10 microns, less than or equal to about 5 microns, less than or equal to about 1,000 nm, less than or equal to about 100 nm, less than or equal to about 50 nm, less than or equal to about 25 nm or less, from a surface of a feature. A feature surface may, for example, be a surface or edge of the die after dicing a wafer. A feature surface may be a surface of a die street (e.g., before dicing of a wafer). A feature surface may be a surface of a via hole or hollow region. A feature surface may be a surface of a semiconductor material.

A feature, such as the plurality of vias 204 and 303 herein, may comprise an average feature size. An average feature size may be characterized by parameters including an average height, and average width or average diameter, an average aspect ratio and an average etch angle. A feature may be round or rectangular shaped. A feature height may be defined by a substrate thickness or layer thickness of a layer in the substrate. A feature may have a width or diameter of at least about 1 micron, at least about 10 microns, at least about 20 microns, at least about 30 microns, at least about 40 microns, at least about 50 microns, at least about 60 microns or greater. A feature may have a width or diameter of less than or equal to about 20 microns. A feature may have a width or diameter of less than or equal to about 40 microns. A feature may have a width or diameter within a range from about 1 micron to about 100 microns, within a range from about 10 microns to about 100 microns, within a range from about 20 microns to about 100 microns, within a range from about 30 microns to about 100 microns or within a range from about 40 microns to about 100 microns, within a range from about 60 microns to about 100 microns or greater. A feature may have a width or diameter within a range from about 10 microns to about 40 microns, within a range from about 10 microns to about 60 microns or greater. A feature may have a height varying from sub-nanometer to hundreds of microns. A feature may have a height less than or equal to about 600 microns. A feature may have a height less than or equal to about 150 microns. A feature may have a height of at least about 1 micron, at least about 25 microns, at least about 50 microns, at least about 100 microns or greater.

A feature, such as the plurality of vias 204 and 303 herein, may be characterized by an aspect ratio or average aspect ratio. In some examples, an aspect ratio (e.g., an average aspect ratio) may be a ratio between a height of a feature and a width or diameter of the feature (e.g., height-to-width aspect ratio). For example, a feature having a height of 100 microns and a diameter or width of 20 microns may have an aspect ratio of 5:1, 5/1 or 5. As another example, a feature having a height of 50 microns and a width of 40 microns may have an aspect ratio of 1.25:1 or 1.25. A feature may have an aspect ratio of at least about 0.25:1. A feature may have an aspect ratio of at least about 1:1, at least about 1.25:1, at least about 2:1, at least about 3:1, at least about 4:1, at least about 5:1, at least about 7:1, at least about 10:1 or greater.

In some examples, an aspect ratio may generally refer to a ratio between a first width or diameter of a feature and a second width or diameter of the feature (e.g., width-to-width aspect ratio). For example, an aspect ratio may refer to a ratio between a width or diameter of a feature on a first surface of a substrate and a width or diameter of the feature on a second surface of the substrate. In some examples, a feature may comprise a first width or diameter on a backside surface of a substrate and a second width or diameter on a frontside surface of the substrate. The backside surface, the frontside surface, or both, may comprise a material having an average thermal conductivity equal to or greater than about 1,000 W/mK. The backside surface, the frontside surface, or both, may comprise diamond. The frontside surface may comprise an interface between diamond and another material different from diamond. The frontside surface may comprise another material different from diamond, for example, a semiconductor containing material.

A substrate may comprise one or more features, such as the plurality of vias 204 and 303 herein, that may be disposed proximate to a device or component of the substrate, such as a transistor. In some examples, such components may be disposed on a surface of the substrate. Components may also be disposed within a substrate, such as within epitaxial layers of a substrate.

In some examples, a distance between a feature and a component may be defined by a distance between a surface or edge of the component and a surface of the feature (e.g., inner surface). A distance between a feature and a component may be, for example, less than or equal to about 200 micrometers (or microns, um, μ), less than or equal to about 100 microns, less than or equal to about 75 microns, less than or equal to about 60 microns, less than or equal to about 50 microns, less than or equal to about 30 microns, less than or equal to about 20 microns, less than or equal to about 15 microns, or less. A distance between a feature and a component may be within a range from about 30 microns to about 20 microns, from about 20 microns to about 10 microns, from about 10 microns to about 5 microns, or less.

### Examples of Elements on a Heat Dissipating Circuit Board

In some cases, the HTcCB comprises repeating the layering operations described herein to produce a layered structure with a desired number of HTc and patterned metal layers. In some cases, a HTcCB may be deployed as an intermediate layer between a PCB and a silicon interposer, die, multi-terminal device, chip, or other components connected to the PCB. In some cases, an HTcCB may be employed as an interposer layer. In some cases, a HTcCB may be employed as an interposer layer mounted directly to a GPU, CPU, or Integrated Circuit to provide heat transfer with direct electrical connections to the circuit using metal bump attachment methods described herein, soldering, conducting epoxy, or other methods to produce electrical connection.

In some cases, the HTcCB may be used to dissipate heat of one or more heat sources attached thereon. In some cases, the HTcCB comprises a heat source attached to the heat dissipating circuit board (HTcCB). A non-limiting example of a heat source 401 attached to a HTcCB 200, herein, is provided in FIG. 4, in accordance with some embodiments.

Examples of heat sources, such as the heat source 401, can include a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source. In some cases, the heat source 401 comprises a transistor. In some cases, the heat source 401 comprises a FET. In some cases, the heat source 401 comprises a MOSFET. In some cases, the heat source 401 comprises a semiconductor chip. In some cases, the heat source 401 comprises a semiconductor die. In some cases, the heat source 401 comprises a CPU. In some cases, the heat source 401 comprises a microcontroller. In some cases, the heat source 401 comprises a GPU. In some cases, the heat source 401 comprises a graphics chip. In some cases, the heat source 401 comprises a chipset. In some cases, the heat source 401 comprises a SoC. In some cases, the heat source 401 comprises a capacitor. In some cases, the heat source 401 comprises a resistor. In some cases, the heat source 401 comprises a regulator. In some cases, the heat source 401 comprises a rectifier. In some cases, the heat source 401 comprises a diode. In some cases, the heat source 401 comprises a transducer. In some cases, the heat source 401 comprises an inductor.

In some cases, the heat source 401 is a chip. A chip may be an active electronic or optoelectronic device disposed on a substrate. A chip may comprise one or more active layers disposed on a substrate. The chip may comprise a layered structure. The chip may comprise one or more transistors (e.g., field-effect transistor, bipolar transistor). A transistor may be a high-electron-mobility transistor. The chip may comprise an integrated circuit, such as a monolithic microwave integrated circuit (MMIC). The chip may perform functions such as mixing, power amplification, low noise amplification, and switching.

In some cases, the heat source 401 is a transistor. A transistor may be an electrical device that can act as a switch and/or an amplifier. A transistor may be a part of a digital circuit. A digital circuit may comprise a plurality of transistors. A transistor may comprise one or more contacts, a layered structure, and a substrate. A transistor may be a part of a computing device. A transistor may be a portion of a logic circuit or a logic gate. A transistor may be a semiconductor device. Afield-effect transistor (FET) may be a transistor that uses an electric field to control the operation of a device. An electric field may be used to control the flow of current between two contacts or terminals in the device such as a source contact and a drain contact.

In some cases, the heat source 401 is a high-electron-mobility transistor. A high-electron-mobility transistor (HEMT) may be a field-effect transistor comprising a heterojunction. A high-electron-mobility transistor may be alternatively referred to as a heterostructure field effect transistor. A heterojunction may refer to the interface between any two solid-state materials of differing material properties. In some examples, these may include any two semiconductors, any two crystalline forms (e.g., amorphous, polycrystalline) of the same semiconductor, any two semiconductors comprising the same element but with varying amounts of those elements, any two semiconductors with varying dopant level, etc. The two materials may have unequal band gaps. The two materials may have a band offset. The two materials forming the heterojunction may be a heterostructure. In some examples, an interface between a buffer layer and a barrier layer may form a heterojunction.

In some cases, the HTcCB 200 further comprises one or more heat dissipating structures attached to the heat dissipating circuit board (HTcCB). A non-limiting example of a heat dissipating structure 402 attached to a HTcCB 200, herein, is provided in FIG. 4, in accordance with some embodiments.

Examples of heat dissipating structure, such as the heat dissipating structure 402 herein, can include a heat sink, a cooling pad, a liquid cooling device, a heat pipe, a vapor chamber, a phase-change cooling device, a thermoelectric cooling device, a Peltier cooling device, a heat spreader, or any suitable heat dissipative structure. In some cases, the heat dissipating structure 402 comprises a heat sink. In some cases, the heat dissipating structure 402 comprises a cooling pad. In some cases, the heat dissipating structure 402 comprises a liquid cooling device. In some cases, the heat dissipating structure 402 comprises a heat pipe. In some cases, the heat dissipating structure 402 comprises a vapor chamber. In some cases, the heat dissipating structure 402 comprises a phase change cooling device. In some cases, the heat dissipating structure 402 comprises a thermoelectric cooling device. In some cases, the heat dissipating structure 402 comprises a Peltier cooling device. In some cases, the heat dissipating structure 402 comprises a heat spreader.

In some cases, metal pads may be deposited on the HTcCB to be used as thermal pads. In some cases, metal pads may be deposited on the HTcCB to be used as thermal pads, wherein the thermal pads connect to the one or more HTc layers of the HTcCB. In some cases, these thermal pads may be mechanically attached to other heat dissipative structures within the system architecture of the HTcCB. In some cases, these thermal pads may be thermally attached to other heat dissipative structures within the system architecture. In some cases, these thermal pads may be mechanically and thermally attached to other heat dissipative structures within the system architecture.

A non-limiting example of metal pads 403 used to attach a heat source 401 or a heat dissipating structure 402 to a HTcCB 200 is provided in FIG. 4, in accordance with some embodiments. In some cases, the heat source 401 is attached to the heat dissipating circuit board by a metal pad 403 formed on the heat dissipating circuit board. In some cases, the metal pad 403 is thermally connected to the second layer 203 of the heat dissipating circuit board. In some cases, the metal pad 403 may be connected to any HTc of a HTcCB, herein. In some cases, the heat dissipating structure 402 is attached to the heat dissipating circuit board by a metal pad 403 formed on the heat dissipating circuit board. In some cases, the metal pad 403 is thermally connected to the second layer 203 of the heat dissipating circuit board. In some cases, the metal pad 403 may be connected to any HTc of a HTcCB, herein.

In one example, the present disclosure provides a HTcCB 200 comprising one or more HTc layers 201, one or more patterned metal layers 202 attached to one or more sides of the one or more HTc layers 201, one or more additional layers 203, 302 attached to the one or more sides of the one or more HTc layers, the additional layers comprising through-holes or vias 204, 303 corresponding to at least a portion of the features of the one or more patterned metal layers 203, 302 on the one or more sides of the one or more HTc layers 201, and one or more patterned metal layers 301 on one or more sides of the one or more additional layers 203, 302 forming a layered structure suitable for use as a heat dissipating circuit board.

### Examples of Methods for Forming a Heat Dissipating Circuit Board

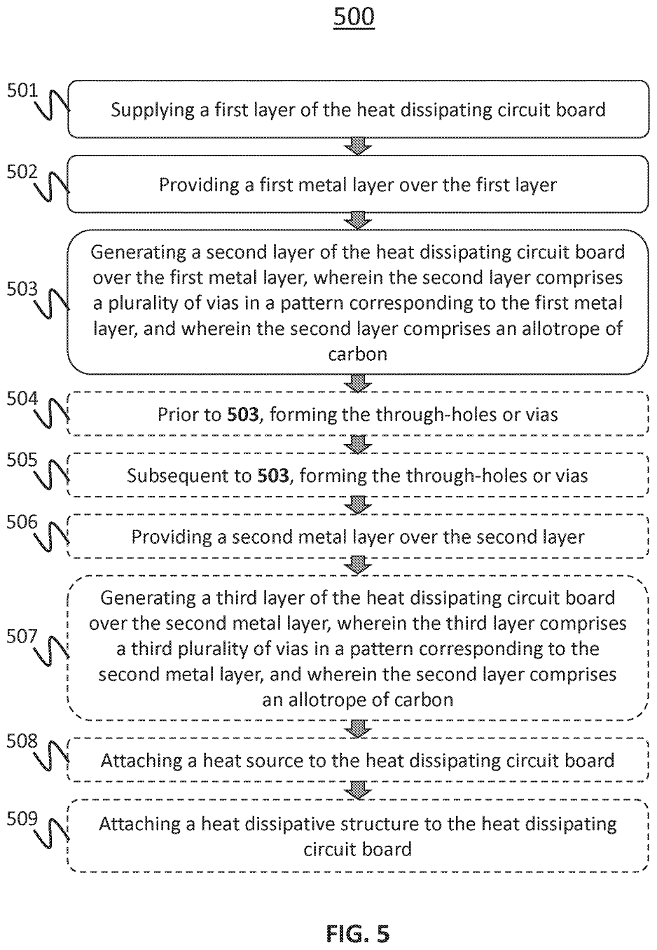

The present disclosure provides a method for forming a heat dissipating circuit board, herein. A non-limiting example of a method 500 for forming a heat dissipating circuit board is provided in FIG. 5, in accordance with some embodiments. In some cases, the method 500, may be used to form any heat dissipating circuit board, herein, such as the HTcCB 200 of FIG. 2, the HTcCB 300 of FIG. 3, or the HTcCB 400 of FIG. 4.

In some cases, the method 500 comprises supplying at 501 a first layer of a heat dissipating circuit board. For example, the first layer of the heat dissipating circuit board supplied at 501 may be the same or substantially the same as the first layer 201 of the HTcCB 200 or 300, herein.

In some cases, the method 500 comprises providing at 502 a first metal layer over the first layer. For example, the first metal layer may be the same or substantially the same as the first metal layer 202 of the HTcCB 200 or 300, herein. In some cases, providing at 502 the first metal layer comprises patterning the metal layer, as described herein.

In some cases, the method 500 comprises generating at 503 a second layer of the heat dissipating circuit board over the first metal layer. For example, the second layer may be the same or substantially the same as the second layer 203 of the HTcCB 200 or 300, herein. In some cases, the second layer comprises a plurality of vias in a pattern corresponding to the first metal layer. For example, the plurality of vias may be the same or substantially the same as the plurality of vias 204 of the HTcCB 200 or 300, herein. In some cases, the second layer comprises an allotrope of carbon. For example, the second layer may comprise diamond. In another example, the second layer may comprise graphene. In a further example, the second layer may comprise graphite.

In some cases, the method further comprises forming at 504 through-holes or vias prior to generating the second layer at 503. In some cases, the method further comprises forming at 505 the through-holes or vias after generating the second layer at 503.

In some cases, the method further comprises providing at 506 a second metal layer over the second layer. For example, the second metal layer may be the same or substantially the same as the metal layer 301 of the HTcCB 300, herein. In some cases, the method further comprises generating at 507 a third layer of the heat dissipating circuit board over the second metal layer. For example, the third layer of the heat dissipating circuit board may be the same or substantially the same as the third layer 302 of the HTcCB 300, herein. For example, the third layer of the heat dissipating circuit board may be an allotrope of carbon. In some cases, the third layer comprises a second plurality of vias in a pattern corresponding to the second metal layer. For example, the second plurality of vias may be the same or substantially the same as the plurality of vias 303 of the HTcCB 300, herein, which may be in a pattern corresponding the second metal layer which may be the same or substantially the same as the second metal layer 301 of the HTcCB 300, herein. In some cases, the second layer of the heat dissipating circuit board is an allotrope of carbon. For example, the second layer of the heat dissipating circuit board may be the same or substantially the same as the second layer 203 of the HTcCB 200 or 300, herein.

In some cases, the method 500 further comprises attaching at 508, a heat source to the heat dissipating circuit board. For example, the heat source may be the same or substantially the same as the heat source 401 of the HTcCB 400, herein. In some cases, the method 500 further comprises attaching at 509, a heat dissipating structure to the heat dissipating circuit board. For example, the heat dissipating structure may be the same or substantially the same as the heat dissipating structure 402 of the HTcCB 400, herein.

While the operations of the method 500 are provided sequentially, this is merely to aid in the understanding of the individual operations. It will be understood that the operations of the method 500 may be performed contemporaneously, and in any order. In some cases, any number of the operations of the method 500 may be repeated to produce a HTcCB with the desired number of layers, the desired thermal properties, or the desired electrical conductivity.

A non-limiting example of a schematic 600 for High Tc Circuit Board (HTcCB) fabrication is shown in FIG. 6, in accordance with some embodiments. A non-limiting example of HTcCB fabrication may comprise the following operations: 1. Use a thin layer of SiC, AlN, Diamond, or other electrically insulative material with higher thermal conductivity than standard co-fired ceramic circuit printed circuit boards. This material layer shall be called the HTc layer. Thin layers may include laser exfoliated or thinly sliced layers of the electrically insulative material; 2. Pattern metal layers, through standard photoresist and metal deposition processes, onto the surface of the HTc layer, such as shown at 601 of the schematic 600; 3. Deposit a second thin layer above said HTc material from Operation 1. onto the now metal patterned surface of the HTc layer. Deposited second layer may be deposited via CVD or some other method, or placed; 4. Vias through the second thin layer, which contact the underlying patterned metal layer, shall be formed either prior to or after the second thin layer has been deposited or placed, as shown at 602 of the schematic 600; 5. If vias are formed prior to placing the second thin layer on the HTc layer, the vias shall be aligned to the patterned metal layer. Connection shall take place using Cu—Cu ultrasonic bump connection process, or any other suitable attachment process; 6. An additional patterned metal layer is added to the opposite surface of the second thin layer, as shown at 603 of the schematic 600; 7. This process shall be repeated for desired amount of HTc layers and metal interconnect layers, as shown at 604 of the schematic 600; 8 The stack of interconnect layers may also be constructed where a high thermally conductive layer, such as diamond, SiC, AlN, or any other high thermally conductive layer is imbedded in a more standard PCB or silicon interposer; 9. Described above HTcCB may also be used as an interposer. The HTcCB used as an interposer may be mounted directly to the GPU/CPU/Integrated Circuit for improved heat transfer and with direct electrical connections to the circuit through Cu—Cu bump connections, soldering, conducting epoxy, or other suitable connection methods.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

### Illustrative Clauses for Methods and Systems for Heat Dissipating Circuit Boards

Clause 1. A method for forming a heat dissipating circuit board, the method comprising: (a) supplying a first layer of the heat dissipating circuit board; (b) providing a first metal layer over the first layer; and (c) generating a second layer of the heat dissipating circuit board over the first metal layer, wherein the second layer comprises a plurality of vias in a pattern corresponding to the first metal layer, and wherein the second layer comprises an allotrope of carbon.

Clause 2. The method of clause 1, wherein the first layer is a polymer.

Clause 3. The method of clause 1, wherein (b) comprises patterning the first metal layer.

Clause 4. The method of clause 3, wherein the plurality of vias in (c) is patterned according to a pattern of the first metal layer.

Clause 5. The method of clause 1, wherein the first layer is a printed circuit board.

Clause 6. The method of clause 1, wherein prior to (c) the method further comprises forming the through-holes or vias.

Clause 7. The method of clause 1, wherein after (c) the method further comprises forming the through-holes or vias.

Clause 8. The method of clause 1, wherein the plurality vias in (c) comprise a through via, a blind via, or buried via.

Clause 9. The method of clause 1, further comprising patterning a second metal layer on a side of the second layer of the layered structure opposite the first metal layer.

Clause 10. The method of clause 1, wherein patterning the first metal layer further comprises a first intermediate layer disposed between the first metal layer and the first layer of heat dissipating circuit board.

Clause 11. The method of clause 10, wherein the first intermediate layer comprises an electrically conductive material.

Clause 12. The method of clause 1, wherein the first layer of the heat dissipating circuit board comprises an electrically insulative material with high thermal conductivity (HTc layer).

Clause 13. The method of clause 12, wherein the first layer has a first side and a second side opposite the first side, and wherein the first metal layer is on the first side of the first layer.

Clause 14. The method of clause 1, further comprising patterning a second metal layer above the second layer of the heat dissipating circuit board.

Clause 15. The method of clause 14, wherein patterning the second metal layer further comprises forming a second intermediate layer disposed between said second metal layer and said second side of the second layer of the heat dissipating circuit board.

Clause 16. The method of clause 15, wherein the second intermediate layer comprises an electrically conductive material.

Clause 17. The method of clause 1, further comprising providing a second metal layer over the second layer.

Clause 18. The method of clause 17, further comprising generating a third layer of the heat dissipating circuit board over the second metal layer, wherein the third layer comprises a second plurality of vias in a pattern corresponding to the second metal layer, and wherein the second layer comprises an allotrope of carbon.

Clause 19. The method of clause 18, wherein the second plurality of vias comprises a through via, a blind via, or buried via.

Clause 20. The method of clause 1, further comprising attaching a heat source to the heat dissipating circuit board.

Clause 21. The method of clause 20, wherein the heat source comprises one or more of a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source.

Clause 22. The method of clause 21, wherein the heat source comprises a transistor.

Clause 23. The method of clause 21, wherein the heat source comprises a FET.

Clause 24. The method of clause 21, wherein the heat source comprises a MOSFET.

Clause 25. The method of clause 21, wherein the heat source comprises a semiconductor chip.

Clause 26. The method of clause 21, wherein the heat source comprises a semiconductor die.

Clause 27. The method of clause 21, wherein the heat source comprises a CPU.

Clause 28. The method of clause 21, wherein the heat source comprises a microcontroller.

Clause 29. The method of clause 21, wherein the heat source comprises a GPU.

Clause 30. The method of clause 21, wherein the heat source comprises a graphics chip.

Clause 31. The method of clause 21, wherein the heat source comprises a chipset.

Clause 32. The method of clause 21, wherein the heat source comprises a SoC.

Clause 33. The method of clause 21, wherein the heat source comprises a capacitor.

Clause 34. The method of clause 21, wherein the heat source comprises a resistor.

Clause 35. The method of clause 21, wherein the heat source comprises a regulator.

Clause 36. The method of clause 21, wherein the heat source comprises a rectifier.

Clause 37. The method of clause 21, wherein the heat source comprises a diode.

Clause 38. The method of clause 21, wherein the heat source comprises a transducer.

Clause 39. The method of clause 21, wherein the heat source comprises an inductor.

Clause 40. The method of clause 1, further comprising attaching a heat dissipative structure to the heat dissipating circuit board.

Clause 41. The method of clause 40, wherein the heat dissipative structure comprises one or more of a heat sink, a cooling pad, a liquid cooling device, a heat pipe, a vapor chamber, a phase-change cooling device, a thermoelectric cooling device, a Peltier cooling device, a heat spreader, or any suitable heat dissipative structure.

Clause 42. The method of clause 40, wherein the heat dissipative structure comprises a heat sink.

Clause 43. The method of clause 40, wherein the heat dissipative structure comprises a cooling pad.

Clause 44. The method of clause 40, wherein the heat dissipative structure comprises a liquid cooling device.

Clause 45. The method of clause 40, wherein the heat dissipative structure comprises a heat pipe.

Clause 46. The method of clause 40, wherein the heat dissipative structure comprises a vapor chamber.

Clause 47. The method of clause 40, wherein the heat dissipative structure comprises a phase-change cooling device.

Clause 48. The method of clause 40, wherein the heat dissipative structure comprises a thermoelectric cooling device.

Clause 49. The method of clause 40, wherein the heat dissipative structure comprises a Peltier cooling device.

Clause 50. The method of clause 40, wherein the heat dissipative structure comprises a heat spreader.

Clause 51. The method of clause 20, wherein attaching the heat source to the heat dissipating circuit board comprises forming a metal pad on the heat dissipating circuit board and attaching the heat source to the metal pad.

Clause 52. The method of clause 51, wherein forming the metal pad on the heat dissipating circuit board comprises thermally connecting the metal pad to the second layer comprising diamond.

Clause 53. The method of clause 40, wherein attaching the heat dissipative structure to the heat dissipating circuit board comprises forming a metal pad on the heat dissipating circuit board and attaching the heat dissipative structure to the metal pad.

Clause 54. The method of clause 53, wherein forming the metal pad on the heat dissipating circuit board comprises thermally connecting the metal pad to the second layer comprising diamond.

Clause 55. The method of clause 1, wherein generating the second layer in (c) comprises depositing the second layer using a deposition method.

Clause 56. The method of clause 55, wherein the deposition method comprises one or more of chemical vapor deposition (CVD), physical vapor deposition (PVD), sputtering, evaporation deposition, thermal deposition, electron beam deposition, atomic layer deposition (ALD), electroplating, electrodeposition, spin coating, spray pyrolysis, molecular beam epitaxy (MBE), or any suitable deposition method.

Clause 57. The method of clause 55, wherein the deposition method comprises CVD.

Clause 58. The method of clause 55, wherein the deposition method comprises PVD.

Clause 59. The method of clause 55, wherein the deposition method comprises sputtering.

Clause 60. The method of clause 55, wherein the deposition method comprises evaporation deposition.

Clause 61. The method of clause 55, wherein the deposition method comprises thermal deposition.

Clause 62. The method of clause 55, wherein the deposition method comprises electron beam deposition.

Clause 63. The method of clause 55, wherein the deposition method comprises ALD.

Clause 64. The method of clause 55, wherein the deposition method comprises electroplating.

Clause 65. The method of clause 55, wherein the deposition method comprises electrodeposition.

Clause 66. The method of clause 55, wherein the deposition method comprises spin coating.

Clause 67. The method of clause 55, wherein the deposition method comprises spray pyrolysis.

Clause 68. The method of clause 55, wherein the deposition method comprises MBE.

Clause 69. The method of clause 1, wherein generating the second layer in (c) comprises attaching the second layer using an attachment method.

Clause 70. The method of clause 69, wherein the attachment method comprises one or more of fusion bonding, direct bonding, adhesive bonding, anodic bonding, eutectic bonding, metal diffusion bonding, or any other suitable bonding method.

Clause 71. The method of clause 69, wherein the attachment method comprises fusion bonding.

Clause 72. The method of clause 69, wherein the attachment method comprises direct bonding.

Clause 73. The method of clause 69, wherein the attachment method comprises adhesive bonding.

Clause 74. The method of clause 69, wherein the attachment method comprises anodic bonding.

Clause 75. The method of clause 69, wherein the attachment method comprises eutectic bonding.

Clause 76. The method of clause 69, wherein the attachment method comprises metal diffusion bonding.

Clause 77. A heat dissipating circuit board comprising: a first layer of the heat dissipating circuit board; a first metal layer on the first layer; and a second layer of the heat dissipating circuit board overlaid on the first metal layer, wherein the second layer comprises a plurality of vias in a pattern corresponding to the first metal layer, and wherein the second layer comprises an allotrope of carbon.

Clause 78. The heat dissipating circuit board of clause 77, wherein the first layer is a polymer.

Clause 79. The heat dissipating circuit board of clause 77, wherein the first metal layer comprises a patterned metal layer.

Clause 80. The heat dissipating circuit board of clause 79, wherein the plurality of vias is patterned according to a pattern of the first metal layer.

Clause 81. The heat dissipating circuit board of clause 77, wherein the first layer is a printed circuit board.

Clause 82. The heat dissipating circuit board of clause 77, wherein the through holes or vias are formed in the second circuit board layer before the second circuit board layer is overlaid on the first metallized layer.

Clause 83. The heat dissipating circuit board of clause 77, wherein the through holes or vias are formed in the second circuit board layer after the second circuit board layer is overlaid on the first metallized layer.

Clause 84. The heat dissipating circuit board of clause 77, wherein the plurality vias comprise a through via, a blind via, or buried via.

Clause 85. The heat dissipating circuit board of clause 77, further comprising a second metal layer patterned on a side of the second layer of the heat dissipating circuit board opposite the first metal layer.

Clause 86. The heat dissipating circuit board of clause 77, wherein the first metal layer further comprises a first intermediate layer disposed between the first metal layer and the first layer of the heat dissipating circuit board.

Clause 87. The heat dissipating circuit board of clause 86, wherein the first intermediate layer comprises an electrically conductive material.

Clause 88. The heat dissipating circuit board of clause 77, wherein the first layer of the high temperature circuit board comprises an electrically insulative material with high thermal conductivity (HTc layer).

Clause 89. The heat dissipating circuit board of clause 77, wherein the first layer has a first side and a second side opposite the first side, and wherein the first metal layer is on the first side of the first layer.

Clause 90. The heat dissipating circuit board of clause 77, further comprising a second metal layer patterned above the second layer of the heat dissipating circuit board.

Clause 91. The heat dissipating circuit board of clause 90, wherein the second metal layer further comprises a second intermediate layer disposed between said second metal layer and said second side of the second layer of the heat dissipating circuit board.

Clause 92. The heat dissipating circuit board of clause 91, wherein the second intermediate layer comprises an electrically conductive material.

Clause 93. The heat dissipating circuit board of clause 77, further comprising a second metal layer patterned over the second layer of the heat dissipating circuit board.

Clause 94. The heat dissipating circuit board of clause 93, further comprising a third layer of the heat dissipating circuit board over the second metal layer, wherein the third layer comprises a second plurality of vias in a pattern corresponding to the second metal layer, and wherein the second layer comprises an allotrope of carbon.

Clause 95. The heat dissipating circuit board of clause 94, wherein the second plurality of vias comprises a through via, a blind via, or buried via.

Clause 96. The heat dissipating circuit board of clause 77, further comprising a heat source attached to the heat dissipating circuit board.

Clause 97. The heat dissipating circuit board of clause 96, wherein the heat source comprises one or more of a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source.

Clause 98. The heat dissipating circuit board of clause 96, wherein the heat source comprises a transistor.

Clause 99. The heat dissipating circuit board of clause 96, wherein the heat source comprises a FET.

Clause 100. The heat dissipating circuit board of clause 96, wherein the heat source comprises a MOSFET.

Clause 101. The heat dissipating circuit board of clause 96, wherein the heat source comprises a semiconductor chip.

Clause 102. The heat dissipating circuit board of clause 96, wherein the heat source comprises a semiconductor die.

Clause 103. The heat dissipating circuit board of clause 96, wherein the heat source comprises a CPU.

Clause 104. The heat dissipating circuit board of clause 96, wherein the heat source comprises a microcontroller.

Clause 105. The heat dissipating circuit board of clause 96, wherein the heat source comprises a GPU.

Clause 106. The heat dissipating circuit board of clause 96, wherein the heat source comprises a graphics chip.

Clause 107. The heat dissipating circuit board of clause 96, wherein the heat source comprises a chipset.

Clause 108. The heat dissipating circuit board of clause 96, wherein the heat source comprises a SoC.

Clause 109. The heat dissipating circuit board of clause 96, wherein the heat source comprises a capacitor.

Clause 110. The heat dissipating circuit board of clause 96, wherein the heat source comprises a resistor.

Clause 111. The heat dissipating circuit board of clause 96, wherein the heat source comprises a regulator.

Clause 112. The heat dissipating circuit board of clause 96, wherein the heat source comprises a rectifier.

Clause 113. The heat dissipating circuit board of clause 96, wherein the heat source comprises a diode.

Clause 114. The heat dissipating circuit board of clause 96, wherein the heat source comprises a transducer.

Clause 115. The heat dissipating circuit board of clause 96, wherein the heat source comprises an inductor.

Clause 116. The heat dissipating circuit board of clause 77, further comprising a heat dissipative structure attached to the heat dissipating circuit board.

Clause 117. The heat dissipating circuit board of clause 116, wherein the heat dissipative structure comprises one or more of a heat sink, a cooling pad, a liquid cooling device, a heat pipe, a vapor chamber, a phase-change cooling device, a thermoelectric cooling device, a Peltier cooling device, a heat spreader, or any suitable heat dissipative structure.

Clause 118. The heat dissipating circuit board of clause 116, wherein the heat dissipative structure comprises a heat sink.

Clause 119. The heat dissipating circuit board of clause 116, wherein the heat dissipative structure comprises a cooling pad.

Clause 120. The heat dissipating circuit board of clause 116, wherein the heat dissipative structure comprises a liquid cooling device.

Clause 121. The heat dissipating circuit board of clause 116, wherein the heat dissipative structure comprises a heat pipe.

Clause 122. The heat dissipating circuit board of clause 116, wherein the heat dissipative structure comprises a vapor chamber.

Clause 123. The heat dissipating circuit board of clause 116, wherein the heat dissipative structure comprises a phase-change cooling device.

Clause 124. The heat dissipating circuit board of clause 116, wherein the heat dissipative structure comprises a thermoelectric cooling device.

Clause 125. The heat dissipating circuit board of clause 116, wherein the heat dissipative structure comprises a Peltier cooling device.

Clause 126. The heat dissipating circuit board of clause 116, wherein the heat dissipative structure comprises a heat spreader.

Clause 127. The heat dissipating circuit board of clause 96, wherein the heat source is attached to the heat dissipating circuit board by a metal pad formed on the heat dissipating circuit board.

Clause 128. The heat dissipating circuit board of clause 127, wherein the metal pad is thermally connected to the second layer of the heat dissipating circuit board.

Clause 129. The heat dissipating circuit board of clause 116, wherein the heat dissipative structure is attached to the heat dissipating circuit board by a metal pad formed on the heat dissipating circuit board.

Clause 130. The heat dissipating circuit board of clause 129, wherein the metal pad is thermally connected to the second layer of the heat dissipating circuit board.

Clause 131. The heat dissipating circuit board of clause 77, wherein the second layer is overlaid using a deposition method.

Clause 132. The heat dissipating circuit board of clause 131, wherein the deposition method comprises one or more of chemical vapor deposition (CVD), physical vapor deposition (PVD), sputtering, evaporation deposition, thermal deposition, electron beam deposition, atomic layer deposition (ALD), electroplating, electrodeposition, spin coating, spray pyrolysis, molecular beam epitaxy (MBE), or any suitable deposition method.

Clause 133. The heat dissipating circuit board of clause 131, wherein the deposition method comprises CVD.

Clause 134. The heat dissipating circuit board of clause 131, wherein the deposition method comprises PVD.

Clause 135. The heat dissipating circuit board of clause 131, wherein the deposition method comprises sputtering.

Clause 136. The heat dissipating circuit board of clause 131, wherein the deposition method comprises evaporation deposition.

Clause 137. The heat dissipating circuit board of clause 131, wherein the deposition method comprises thermal deposition.

Clause 138. The heat dissipating circuit board of clause 131, wherein the deposition method comprises electron beam deposition.

Clause 139. The heat dissipating circuit board of clause 131, wherein the deposition method comprises ALD.

Clause 140. The heat dissipating circuit board of clause 131, wherein the deposition method comprises electroplating.

Clause 141. The heat dissipating circuit board of clause 131, wherein the deposition method comprises electrodeposition.

Clause 142. The heat dissipating circuit board of clause 131, wherein the deposition method comprises spin coating.

Clause 143. The heat dissipating circuit board of clause 131, wherein the deposition method comprises spray pyrolysis.

Clause 144. The heat dissipating circuit board of clause 131, wherein the deposition method comprises MBE.

Clause 145. The heat dissipating circuit board of clause 77, wherein the second layer is overlaid using an attachment method.

Clause 146. The heat dissipating circuit board of clause 145, wherein the attachment method comprises one or more of fusion bonding, direct bonding, adhesive bonding, anodic bonding, eutectic bonding, metal diffusion bonding, or any other suitable bonding method.

Clause 147. The heat dissipating circuit board of clause 145, wherein the attachment method comprises fusion bonding.

Clause 148. The heat dissipating circuit board of clause 145, wherein the attachment method comprises direct bonding.

Clause 149. The heat dissipating circuit board of clause 145, wherein the attachment method comprises adhesive bonding.

Clause 150. The heat dissipating circuit board of clause 145, wherein the attachment method comprises anodic bonding.

Clause 151. The heat dissipating circuit board of clause 145, wherein the attachment method comprises eutectic bonding.

Clause 152. The heat dissipating circuit board of clause 145, wherein the attachment method comprises metal diffusion bonding.

Clause 153. The heat dissipating circuit board of clause 77 wherein the first layer comprises diamond.

Clause 154. The heat dissipating circuit board of clause 77, wherein the second layer comprises diamond.

Clause 155. The method of clause 1 or 18, wherein the allotrope of carbon is diamond.

Clause 156. The method of clause 1 or 18, wherein the allotrope of carbon is natural diamond.

Clause 157. The method of clause 1 or 18, wherein the allotrope of carbon is synthetic diamond.

Clause 158. The method of clause 1 or 18, wherein the allotrope of carbon is polycrystalline diamond.

Clause 159. The method of clause 1 or 18, wherein the allotrope of carbon is composite diamond.

Clause 160. The method of clause 1 or 18, wherein the allotrope of carbon is diamond-like carbon.

Clause 161. The method of clause 1 or 18, wherein the allotrope of carbon is graphite.

Clause 162. The method of clause 1 or 18, wherein the allotrope of carbon is graphene.

Clause 163. The heat dissipating circuit board of clause 77 or 94, wherein the allotrope of carbon is diamond.

Clause 164. The heat dissipating circuit board of clause 77 or 94, wherein the allotrope of carbon is natural diamond.

Clause 165. The heat dissipating circuit board of clause 77 or 94, wherein the allotrope of carbon is synthetic diamond.

Clause 166. The heat dissipating circuit board of clause 77 or 94, wherein the allotrope of carbon is polycrystalline diamond.

Clause 167. The heat dissipating circuit board of clause 77 or 94, wherein the allotrope of carbon is diamond-like carbon.

Clause 168. The heat dissipating circuit board of clause 77 or 94, wherein the allotrope of carbon is graphite.

Clause 169. The heat dissipating circuit board of clause 77 or 94, wherein the allotrope of carbon is graphene.

What is claimed is:

1. A method for forming a heat dissipating circuit board, the method comprising:
(a) supplying a first layer of the heat dissipating circuit board;
(b) providing a first metal layer over the first layer; and
(c) generating a second layer of the heat dissipating circuit board over the first metal layer, wherein the second layer comprises a plurality of vias in a pattern corresponding to the first metal layer, and wherein the second layer comprises an allotrope of carbon.

2. The method of claim 1, wherein the first layer is a polymer.

3. The method of claim 1, wherein (b) comprises patterning the first metal layer.

4. The method of claim 3, wherein the plurality of vias in (c) is patterned according to a pattern of the first metal layer.

5. The method of claim 1, wherein the first layer is a printed circuit board.

6. The method of claim 1, wherein prior to (c) the method further comprises forming the through-holes or vias prior to or after (c).

7. The method of claim 1, wherein the plurality of vias in (c) comprise a through via, a blind via, or buried via.

8. The method of claim 1, further comprising patterning a second metal layer on a side of the second layer of the layered structure opposite the first metal layer.

9. The method of claim 1, wherein patterning the first metal layer further comprises a first intermediate layer disposed between the first metal layer and the first layer of heat dissipating circuit board.

10. The method of claim 9, wherein the first intermediate layer comprises an electrically conductive material.

11. The method of claim 1, wherein the first layer of the heat dissipating circuit board comprises an electrically insulative material with high thermal conductivity (HTc layer).

12. The method of claim 11, wherein the first layer has a first side and a second side opposite the first side, and wherein the first metal layer is on the first side of the first layer.

13. The method of claim 1, further comprising patterning a second metal layer above the second layer of the heat dissipating circuit board.

14. The method of claim 13, wherein patterning the second metal layer further comprises forming a second intermediate layer disposed between said second metal layer and said second side of the second layer of the heat dissipating circuit board.

15. The method of claim 14, wherein the second intermediate layer comprises an electrically conductive material.

16. The method of claim 1, further comprising providing a second metal layer over the second layer.

17. The method of claim 16, further comprising generating a third layer of the heat dissipating circuit board over the second metal layer, wherein the third layer comprises a second plurality of vias in a pattern corresponding to the second metal layer, and wherein the second layer comprises an allotrope of carbon.

18. The method of claim 17, wherein the second plurality of vias comprises a through via, a blind via, or buried via.

19. The method of claim 1, further comprising attaching to the heat dissipating circuit board one or more of a transistor, a field effect transistor (FET), a metal-oxide semiconductor field effect transistor (MOSFET), a semiconductor chip, a semiconductor die, a central processing unit (CPU), a microcontroller, a graphics processing unit (GPU), a graphics chip, a chipset, a circuit board on a chip (SoC), a capacitor, a resistor, a regulator, a rectifier, a diode, a transducer, an inductor, or any other heat source.

20. The method of claim 1, further comprising attaching a heat dissipative structure to the heat dissipating circuit board, wherein the heat dissipative structure comprises one or more of a heat sink, a cooling pad, a liquid cooling device, a heat pipe, a vapor chamber, a phase-change cooling device, a thermoelectric cooling device, a Peltier cooling device, a heat spreader, or any suitable heat dissipative structure.
